(19) United States
(12) Patent Application Publication
(10) Pub. No.: US 2024/0081047 A1
(43) Pub. Date: Mar. 7, 2024

(54) SEMICONDUCTOR DEVICE INCLUDING SPACER STRUCTURE HAVING OXIDIZED REGION

(71) Applicant: SAMSUNG ELECTRONICS CO., LTD., Suwon-si (KR)

(72) Inventors: Teawon Kim, Suwon-si (KR); Seohee Park, Suwon-si (KR); Yongsuk Tak, Suwon-si (KR); Minkyung Kang, Suwon-si (KR); Joonnyung Heo, Suwon-si (KR)

(21) Appl. No.: 18/351,422

(22) Filed: Jul. 12, 2023

(30) Foreign Application Priority Data
Sep. 2, 2022 (KR) 10-2022-0111099

(51) Int. Cl. H10B 12/00

(52) U.S. Cl. CPC H10B 12/482; H10B 12/02; H10B 12/315; H10B 12/34

(57) ABSTRACT

A semiconductor device includes a conductive pattern and a spacer structure disposed on a side surface of the conductive pattern. The spacer structure includes an inner spacer in contact with the side surface of the conductive pattern, an outer spacer spaced apart from the side surface of the conductive pattern, and an air gap disposed between the inner spacer and the outer spacer. The inner spacer includes an inner oxidized region exposed by the air gap. A concentration of oxygen in the inner oxidized region has a gradient in which the oxygen concentration decreases in a direction away from the air gap.

### CROSS-REFERENCE TO RELATED APPLICATION(S)

This application claims priority under 35 U.S.C. § 119 from Korean Patent Application No. 10-2022-0111099, filed on Sep. 2, 2022 in the Korean Intellectual Property Office, the contents of which are herein incorporated by reference in their entirety.

### TECHNICAL FIELD

Embodiments of present disclosure are directed to a semiconductor device that includes a spacer structure that has an oxidized region.

### DISCUSSION OF THE RELATED ART

As integration density of semiconductor devices has increased, intervals between interconnections have been narrowed. As the intervals between the interconnection are narrowed, a transmission speed of an electrical signal may be reduced due to RC delay.

### SUMMARY

Exemplary embodiments provide a semiconductor device that includes a spacer structure that reduces parasitic capacitance between conductive patterns.

Exemplary embodiments provide a method of fabricating the above-mentioned semiconductor device.

According to an exemplary embodiment, a semiconductor device includes a conductive pattern and a spacer structure disposed on a side surface of the conductive pattern. The spacer structure includes an inner spacer in contact with the side surface of the conductive pattern, an outer spacer that is spaced apart from the side surface of the conductive pattern, and an air gap disposed between the inner spacer and the outer spacer. The inner spacer includes an inner oxidized region exposed by the air gap, and a concentration of oxygen in the inner oxidized region has a gradient in which the oxygen concentration decreases in a direction away from the air gap.

According to an exemplary embodiment, a semiconductor device includes a conductive pattern ana spacer structure disposed on a side surface of the conductive pattern. The spacer structure includes an inner spacer in contact with the side surface of the conductive pattern, an outer spacer that is spaced apart from the side surface of the conductive pattern, and an air gap disposed between the inner spacer and the outer spacer. The inner spacer includes an inner oxidized region exposed by the air gap, and the outer spacer includes an outer oxidized region exposed by the air gap and an outer non-oxidized region in contact with the outer oxidized region.

According to an exemplary embodiment, a semiconductor device includes an active region, an isolation region disposed on a side surface of the active region, a gate structure disposed in a gate trench that intersects the active region and extends into the isolation region, a first impurity region and a second impurity region disposed in the active region adjacent to the gate structure and that are spaced apart from each other, a plurality of structures that intersect the gate structure at a higher level than a level of the gate structure, a contact plug that includes a portion disposed between the plurality of structures and electrically connected to the first impurity region, and spacer structures disposed on side surfaces of the plurality of structures. Each of the plurality of structures includes a bit line and an insulating capping pattern disposed on the bit line. The bit line includes a first bit line portion disposed on the isolation region, and a second bit line portion that includes a lower surface disposed at a level lower that is than a level of a lower surface of the first bit line portion, and that vertically overlaps the second impurity region. Each of the spacer structures includes a first spacer portion disposed on a side surface of the first bit line portion and a second spacer portion disposed on a side surface of the second bit line portion. The first spacer portion includes a first inner spacer in contact with a side surface of the first bit line portion, a first outer spacer, and a first air gap disposed between the first inner spacer and the first outer spacer. The second spacer portion includes a second inner spacer in contact with a side surface of the second bit line portion, a second outer spacer, and a second air gap disposed between the second inner spacer and the second outer spacer. Each of the first and second inner spacers includes an inner oxidized region. A concentration of oxygen in the inner oxidized region of the first inner spacer has a gradient in which the oxygen concentration decreases in a direction away from the first air gap. A concentration of oxygen in the inner oxidized region of the second inner spacer has a gradient in which the oxygen concentration decreases in a direction away from the second air gap.

### BRIEF DESCRIPTION OF DRAWINGS

FIG. 1 is a cross-sectional view of a semiconductor device according to an embodiment.

FIG. 2 is a graph of concentration gradients of an element of a semiconductor device according to an embodiment.

FIG. 3 is a cross-sectional view of a modified example of a semiconductor device according to an embodiment.

FIG. 4 is a cross-sectional view of a modified semiconductor device according to an embodiment.

FIG. 5 is a cross-sectional view of a modified semiconductor device according to an embodiment.

FIG. 6 is a cross-sectional view of a modified semiconductor device according to an embodiment.

FIGS. 7, 8A, 8B, and 9 are illustrate modified semiconductor devices according to embodiments.

FIG. 10 is a flowchart of a method of fabricating a semiconductor device according to an embodiment.

### DETAILED DESCRIPTION

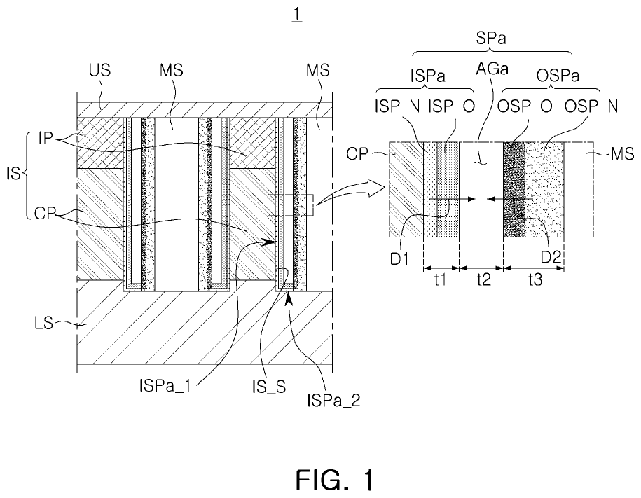

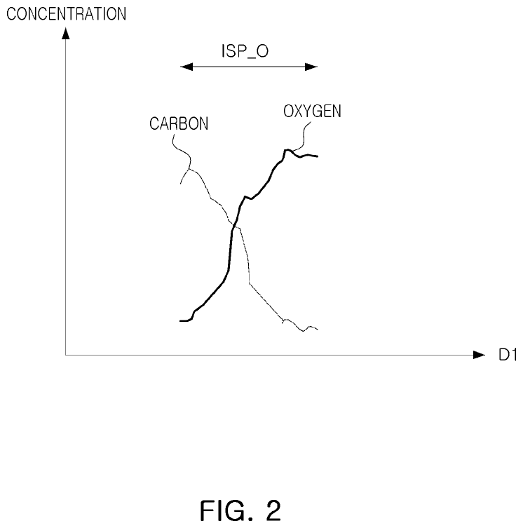

Referring to FIGS. 1 and 2, a semiconductor device according to an embodiment will be described. FIG. 1 is a cross-sectional view of a semiconductor device according to an embodiment, and FIG. 2 is a graph of concentration gradients of a element of a semiconductor device according to an embodiment, such as concentration gradients of carbon and oxygen in an inner oxidized region ISP_O.

Referring to FIGS. 1 and 2, a semiconductor device 1 according to an embodiment includes a lower structure LS, structures IS disposed on the lower structure LS, and spacer structures SPa disposed on respective side surfaces IS_S of the structures IS.

The semiconductor device 1 further includes a middle structure MS disposed between the spacer structures SPa and between adjacent structures IS.

The semiconductor device 1 further includes an upper structure US disposed on the structures IS, the spacer structures SPa, and the middle structure MS.

Hereinafter, a single structure IS of the structures IS and a single spacer structure SPa of the spacer structures SPa will be mainly described for convenience of description.

The structure IS includes a conductive pattern CP. The conductive pattern CP includes at least one conductive material layer. For example, the conductive pattern CP includes conductive material layers that are sequentially stacked.

The conductive pattern CP may be a bit line, etc., of a DRAM, but embodiments are not necessarily limited thereto. For example, the conductive pattern CP may be one of a gate electrode, an interconnection line, a contact plug, etc.

The lower structure LS and the upper structure US vary depending on the type of the conductive pattern CP. For example, when the conductive pattern CP is a gate electrode, the lower structure LS includes a semiconductor substrate, the upper structure US includes an insulating layer, etc., and the middle structure MS includes an insulating layer or a contact plug.

Alternatively, when the conductive pattern CP is a bit line, the lower structure LS includes a semiconductor substrate and a word line, the upper structure US includes an insulating layer, and the middle structure MS includes an insulating layer or a contact plug.

The structure IS further includes an insulating capping pattern IP disposed on the conductive pattern CP. The conductive pattern CP and the insulating capping pattern IP are sequentially stacked. The insulating capping pattern IP includes an insulating material such as a silicon nitride.

The spacer structure SPa contacts the side surface IS_S of the structure IS. The spacer structure SPa contacts a side surface of the conductive pattern CP. The spacer structure SPa contacts a side surface of the conductive pattern CP and a side surface of the insulating capping pattern IP.

The spacer structure SPa includes an inner spacer ISPa, an outer spacer OSPa, and an air gap AGa between the inner spacer ISPa and the outer spacer OSPa.

At least a portion of the inner spacer ISPa contacts the side surface IS_S of the structure IS, such as the side surface of the conductive pattern CP and the side surface of the insulating capping pattern IP.

The inner spacer ISPa includes a first portion ISPa_1 that contacts the side surface IS_S of the structure IS, and a second portion ISPa_2 that extends from a lower portion of the first portion ISPa_1 to a lower portion of the air gap AGa. The second portion ISPa_2 of the inner spacer ISPa vertically overlaps the air gap AGa. An upper portion of the air gap AGa is defined by the upper structure US.

The inner spacer ISPa includes an inner oxidized region ISP_O exposed by the air gap AGa. The inner spacer ISPa further includes an inner non-oxidized region ISP_N. The inner non-oxidized region ISP_N contacts the inner oxidized region ISP_O and is spaced apart from the air gap AGa. The inner oxidized region ISP_O is disposed between the inner non-oxidized region ISP_N and the air gap AGa.

The inner non-oxidized region ISP_N contacts the side surface IS_S of the structure IS, such as the side surface of the conductive pattern CP and the side surface of the insulating capping pattern IP. The inner non-oxidized region ISP_N serves as a barrier that prevents the side surface of the conductive pattern CP from being oxidized by the inner oxidized region ISP_O. Accordingly, the inner non-oxidized region ISP_N can prevent the side surface of the conductive pattern CP from being oxidized and prevent the resistance of the conductive pattern CP from increasing.

The outer spacer OSPa includes an outer oxidized region OSP_O and an outer non-oxidized region OSP_N.

The outer oxidized region OSP_O is exposed by the air gap AGa. The outer non-oxidized region OSP_N contacts the outer oxidized region OSP_O and is spaced apart from the air gap AGa. The outer oxidized region OSP_O is disposed between the outer non-oxidized region OSP_N and the air gap AGa. A thickness of the outer non-oxidized region OSP_N is greater than a thickness of the outer oxidized region OSP_O.

The inner oxidized region ISP_O includes a SiOCN material layer formed by oxidizing a SiCN material layer. The inner non-oxidized region ISP_N includes a SiCN material layer. For example, the inner non-oxidized region ISP_N is formed of a SiCN material, and the inner oxidized region ISP_O is formed of a SiOCN material formed by oxidizing the SiCN material.

In the SiCN material of the inner non-oxidized region ISP_N, Si is included in an amount of about 25 at % to about 45 at %, C is included in an amount of about 10 at % to about 40 at %, and N is included in an amount of about 10 at % to about 40 at %. For example, the inner non-oxidized region ISP_N may be formed of a SiCN material that includes about 25 at % to about 45 at % of Si, about 10 at % to about 40 at % of C, and about 10 at % to about 40 at % of N. The inner oxidized region ISP_O may be formed of a SiOCN material that includes about 20 at % to about 50 at % of 0.

As illustrated in FIG. 2, a concentration of oxygen in the inner oxidized region ISP_O has a gradient in which the oxygen concentration increases in a first direction D1. The first direction D1 is perpendicular to the side surface IS_S of the structure IS (e.g., the side surface of the conductive pattern CP), and is directed toward the air gap AGa from the side surface IS_S of the structure IS (e.g., the side surface of the conductive pattern CP). For example, the concentration of oxygen in the inner oxidized region ISP_O has a gradient in which the oxygen concentration decreases in a direction away from the air gap AGa.

As illustrated in FIG. 2, a concentration of carbon in the inner oxidized region ISP_O has a gradient in which the carbon concentration decreases in the first direction D1. For example, the concentration of carbon in the inner oxidized region ISP_O has a gradient in which the carbon concentration increases in a direction away from the air gap AGa.

A concentration of oxygen in the outer oxidized region OSP_O has a gradient in which the oxygen concentration increases in a second direction D2 toward the air gap AGa from the middle structure MS. For example, the concentration of oxygen in the outer oxidized region OSP_O has a gradient in which the oxygen concentration decreases in a direction away from the air gap AGa.

For example, a material of the outer oxidized region OSP_O differs from a material of the inner oxidized region ISP_O. For example, the inner oxidized region ISP_O includes a SiOCN material formed by oxidizing a SiCN material, and the outer oxidized region OSP_O may include a SiON material formed by oxidizing a SiN material. The inner non-oxidized region ISP_N includes a SiCN material, and the outer non-oxidized region OSP_N includes a SiN material.

For another example, the outer oxidized region OSP_O includes the same material as the inner oxidized region ISP_O. For example, the inner oxidized region ISP_O and the outer oxidized region OSP_O each include a SiOCN material formed by oxidizing a SiCN material.

For another example, the outer non-oxidized region OSP_N includes at least two material layers, such as a SiCN material layer adjacent to or in contact with the outer oxidized region OSP_O, and a SiCN material layer in contact with the SiCN material layer and spaced apart from the outer oxidized region OSP_O.

In an embodiment, a thickness t1 of the inner spacer ISPa ranges from about 5 angstroms (Å) to about 30 Å.

In an embodiment, a thickness t1 of the inner spacer ISPa ranges from about 7 Å to about 25 Å.

A width t2 of the air gap AGa is greater than the thickness t1 of the inner spacer ISPa.

A thickness t3 of the outer spacer OSPa is greater than the thickness t1 of the inner spacer ISPa.

The thickness t3 of the outer spacer OSPa is greater than the width t2 of the air gap AGa.

In an embodiment, the width t2 of the air gap AGa is greater than the thickness t1 of the inner spacer ISPa, and is less than three times the thickness t1 of the inner spacer ISPa. In an embodiment, the width t2 of the air gap AGa is greater than the thickness t1 of the inner spacer ISPa, and is less than 1.5 times the thickness t1 of the inner spacer ISPa.

In an embodiment, the thickness t3 of the outer spacer OSPa is greater than the thickness t1 of the inner spacer ISPa, and is less than three times the thickness t1 of the inner spacer ISPa. In an embodiment, the thickness t3 of the outer spacer OSPa is greater than the thickness t1 of the inner spacer ISPa, and is less than twice the thickness t1 of the inner spacer ISPa.

Hereinafter, various modified examples of elements of the above-described embodiment will be described. Various modified examples of the elements of the above-described embodiment to be described below will be mainly described with respect to modified or replaced elements. In addition, modifiable or replaceable elements to be described below may be combined with each other or may be combined with the above-described elements to constitute a memory device according to an embodiment.

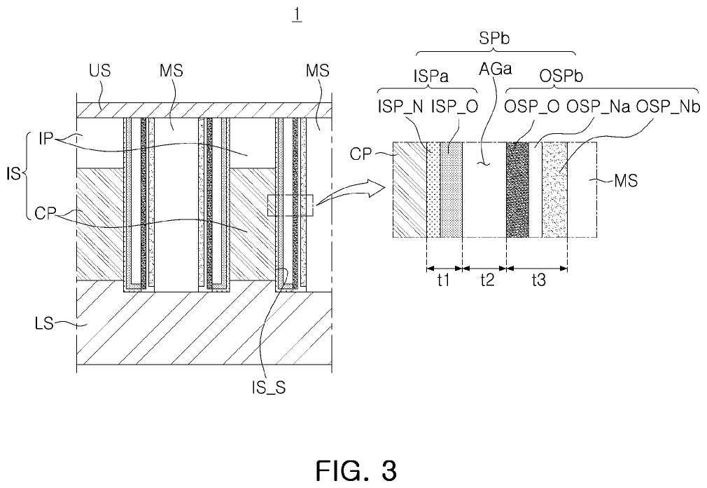

Various modified examples of the above-described spacer structure SPa will be described with reference to FIGS. 3, 4, 5, and 6, respectively. FIGS. 3, 4, 5, and 6 are cross-sectional views of modified examples of a semiconductor device according to an embodiment.

In a modified example according to an embodiment, referring to FIG. 3, the outer spacer OSPa of FIG. 1 is modified into an outer spacer OSPb, as illustrated in FIG. 3. For example, the outer non-oxidized region OSP_N of the outer spacer OSPa of FIG. 1 is replaced with a first outer non-oxidized region OSP_Na and a second outer non-oxidized region OSP_Nb as illustrated in FIG. 3. Accordingly, the outer spacer OSPb includes the outer oxidized region OSP_O, the first outer non-oxidized region OSP_Na in contact with the outer oxidized region OSP_O, and the second outer non-oxidized region OSP_Nb in contact with the first outer non-oxidized region OSP_Na. The first outer non-oxidized region OSP_Na is disposed between the second outer non-oxidized region OSP_Nb and the outer oxidized region OSP_O.

The first outer non-oxidized region OSP_Na and the second outer non-oxidized region OSP_Nb include different materials. For example, the first outer non-oxidized region OSP_Na includes a SiCN material, and the second outer non-oxidized region OSP_Nb includes a SiN material. The outer oxidized region OSP_O includes a SiOCN material formed by oxidizing a SiCN material.

Accordingly, the spacer structure SPa of FIG. 1 is modified into a spacer structure SPb that includes the inner spacer ISPa, the air gap AGa, and the outer spacer OSPb.

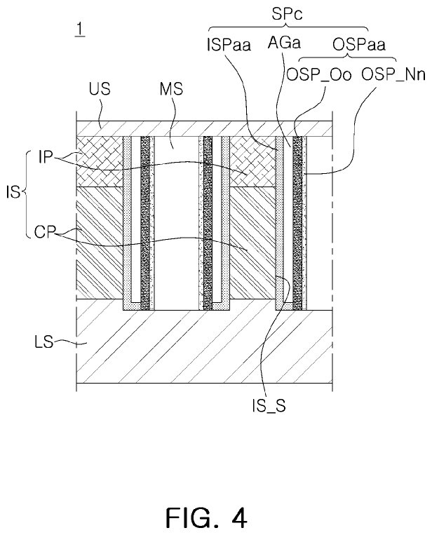

In a modified example according to an embodiment, referring to FIG. 4, the inner spacer ISPa of FIG. 1 may be modified into an inner spacer ISPaa, as illustrated in FIG. 4. The inner spacer ISPaa is formed of an inner oxidized region without a non-oxidized region. The outer spacer OSPa of FIG. 1 is modified into an outer spacer OSPaa that includes an outer oxidized region OSP_Oo that has an increased thickness and an outer non-oxidized region OSP_Nn that has a decreased thickness.

Accordingly, the spacer structure SPa of FIG. 1 is modified into a spacer structure SPc that includes the inner spacer ISPaa, the air gap AGa, and the outer spacer OSPaa.

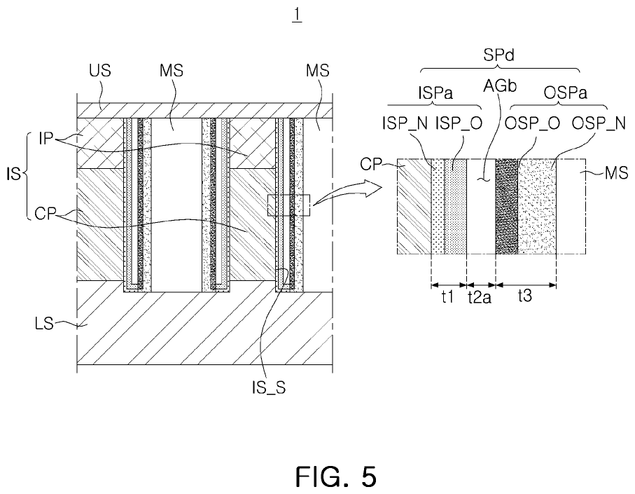

In a modified example according to an embodiment, referring to FIG. 5, the air gap AGa of FIG. 1 is modified into an air gap AGb that has a decreased width, as illustrated in FIG. 5.

A width t2a of the air gap AGb is less than or equal to the thickness t1 of the inner spacer ISPa. A thickness t3 of the outer spacer OSPa is greater than the thickness t1 of the inner spacer ISPa, and the thickness t3 of the outer spacer OSPa is greater than the width t2a of the air gap AGb. The width t2a of the air gap AGb is less than the thickness t1 of the inner spacer ISPa, and is greater than about 0.5 times the thickness t1 of the inner spacer ISPa.

Accordingly, the spacer structure SPa in FIG. 1 is modified into a spacer structure SPd that includes the inner spacer ISPa, the air gap AGb, and the outer spacer OSPa.

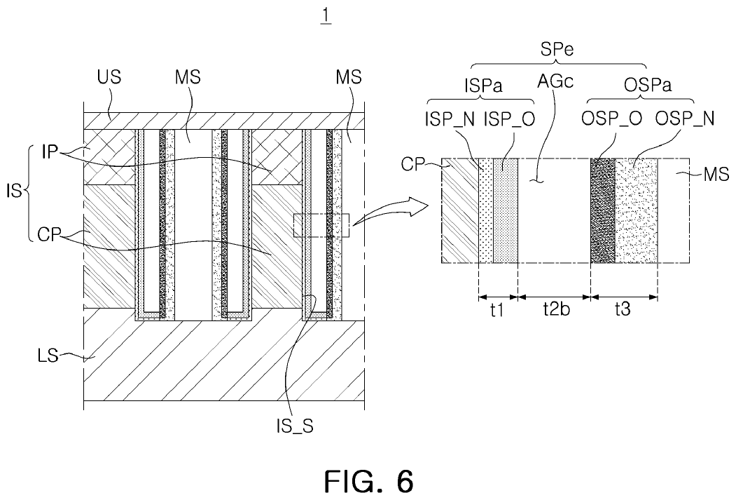

In a modified example according to an embodiment, referring to FIG. 6, the air gap AGa of FIG. 1 is modified into an air gap AGc that has an increased width, as illustrated in FIG. 6.

A width t2b of the air gap AGc is greater than the thickness t3 of the outer spacer OSPa, and the thickness t3 of the outer spacer OSPa is greater than the thickness t1 of the inner spacer ISPa.

Accordingly, the spacer structure SPa of FIG. 1 is modified into a spacer structure SPe that includes the inner spacer ISPa, the air gap AGc, and the outer spacer OSPa.

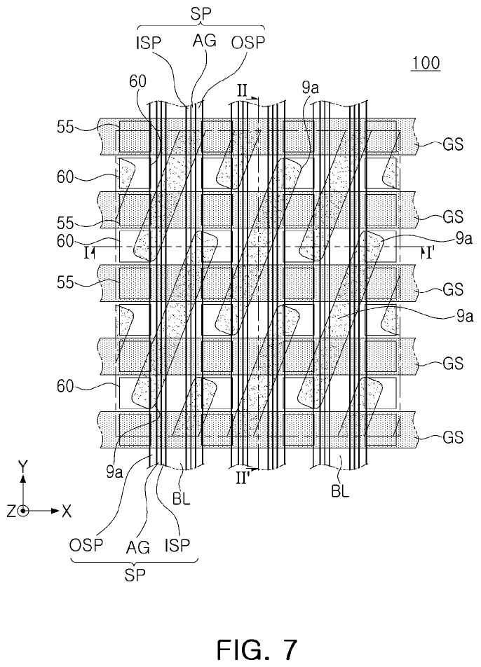

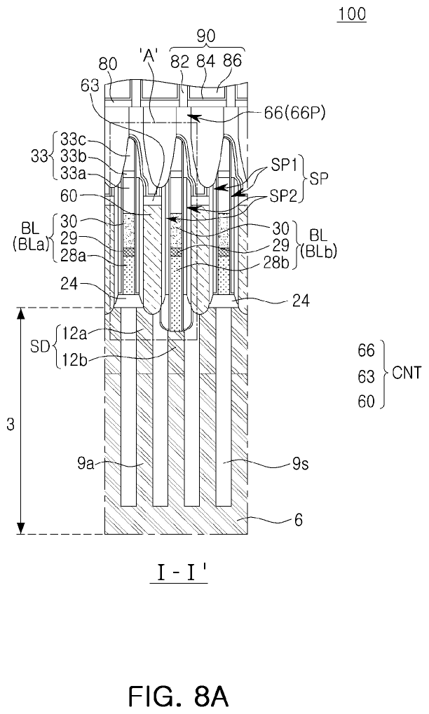

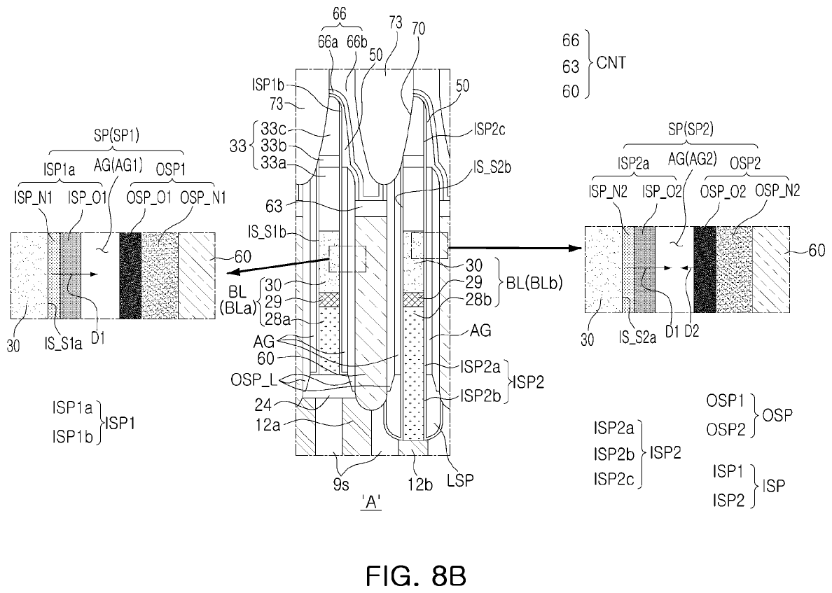

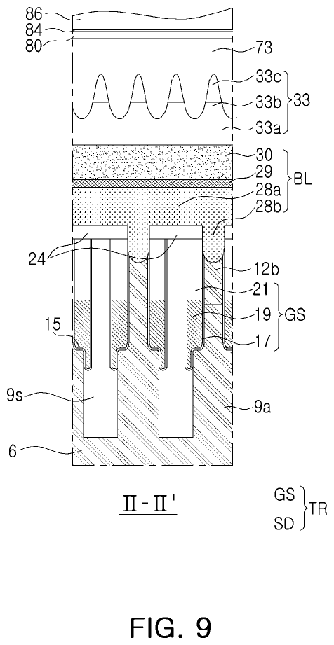

Hereinafter, a semiconductor device according to an embodiment will be described with reference to FIGS. 7, 8A, 8B, and 9. FIG. 7 is a plan view of a modified example of a semiconductor device according to an embodiment, FIG. 8A is a cross-sectional view taken along line I-I′ of FIG. 7, FIG. 8B is a partially enlarged view of region ‘A’ of FIG. 8A, and FIG. 9 is a cross-sectional view taken along line II-II′ of FIG. 7.

Referring to FIGS. 7, 8A, 8B, and 9, a semiconductor device 100 according to an embodiment includes a substrate 6, an active region 9a disposed on the substrate 6, an isolation region 9s disposed on a side surface of the active region 9a, a gate trench 15 that intersects the active region 9a and extends into the isolation region 9s, a gate structure GS disposed in the gate trench 15, and a first impurity region 12a and a second impurity region 12b disposed in the active region 9a adjacent to the gate structure GS and spaced apart from each other.

The semiconductor device 100 further includes a buffer pattern 24, bit lines BL and insulating capping patterns 33 that are sequentially stacked. The buffer pattern 24 is disposed on the gate structure GS, the isolation region 9s, and the active region 9a. Each of the bit lines BL includes a line portion 28a disposed on the buffer pattern 24, and a plug portion 28b that penetrates through the buffer pattern 24 and electrically connects to the second impurity region 12b.

The substrate 6 may be a semiconductor substrate. For example, the substrate 6 includes at least one of a group IV semiconductor, a group III-V compound semiconductor, or a group II-VI compound semiconductor. For example, the group IV semiconductor includes at least one of silicon, germanium, or silicon-germanium. For example, the substrate 6 includes a silicon material, such as a single-crystalline silicon material. The substrate 6 may be one of a silicon substrate, a silicon-on-insulator (SOI) substrate, a germanium substrate, a germanium-on-insulator (GOI) substrate, a silicon-germanium substrate, or a substrate that includes an epitaxial layer.

The isolation region 9s may be a trench isolation layer. The isolation region 9s is disposed on the substrate 6 and defines the active region 9a. The isolation region 9s includes an insulating material such as a silicon oxide and/or a silicon nitride.

The gate structure GS has a line shape that extends in a first direction X, and the active region 9a has a bar shape that extends in an oblique direction that intersects the first direction X while forming an obtuse angle or an acute angle. The bit lines BL have a line shape that extends in a second direction Y perpendicular to the first direction X.

A plurality of active regions 9a are provided. A plurality of gate structures GS are provided. A single active region 9a intersects a pair of adjacent gate structures GS, and intersects one of the plurality of bit lines BL.

Hereinafter, a single active region 9a, a single gate structure GS, and a single bit line BL will be mainly described.

The gate structure GS includes a gate dielectric layer 17 that covers an internal wall of the gate trench 15, a gate electrode 19 that fills a portion of the gate trench 15 on the gate dielectric layer 17, and a gate capping layer 21 that fills a remaining portion of the gate trench 15 on the gate electrode 19.

The gate dielectric layer 17 includes at least one of a silicon oxide or a high-K dielectric. The gate electrode 19 includes at least one of doped polysilicon, a metal, a conductive metal nitride, a metal-semiconductor compound, a metal alloy, a conductive metal oxide, graphene, carbon nanotubes, or combinations thereof. For example, the gate electrode 19 includes at least one of polysilicon (e.g., doped polysilicon), Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotubes, or combinations thereof, but embodiments are not necessarily limited thereto. The gate electrode 19 may have a single-layer structure or a multilayer structure of the above-mentioned materials. The gate capping layer 21 includes an insulating material, such as a silicon nitride.

The first and second impurity regions 12a and 12b in the active region 9a are spaced apart from each other by the gate structure GS, and may be first and second source/drain regions. The first and second impurity regions 12a and 12b and the gate structure GS constitute a transistor TR. The first impurity region 12a and the second impurity region 12b may be collectively referred to as a source/drain region SD.

The buffer pattern 24 includes a plurality of insulating layers that are sequentially stacked. For example, the buffer pattern 24 includes at least two material layers, such as a silicon oxide layer and a silicon nitride layer.

The bit lines BL include at least one of doped polysilicon, a metal, a conductive metal nitride, a metal-semiconductor compound, a metal alloy, a conductive metal oxide, graphene, carbon nanotubes, or combinations thereof. For example, the bit lines BL include at least one of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotubes, or combinations thereof, but embodiments are not necessarily limited thereto. For example, each of the bit lines BL includes first conductive layers 28a and 28b, a second conductive layer 29, and a third conductive layer 30 that are sequentially stacked. The first conductive layers 28a and 28b include the line portion 28a that is disposed on the buffer pattern 24, and the plug portion 28b that penetrates through the buffer pattern 24 and electrically connects to the second impurity region 12b.

The first conductive layers 28a and 28b include doped polysilicon, such as N-type polysilicon. The second conductive layer 29 includes at least one of a metal-semiconductor compound or a conductive barrier. For example, the metal-semiconductor compound includes at least one of WSi, TiSi, TaSi, NiSi, or CoSi, and the conductive barrier includes at least one of TiN, TaN, WN, TiSiN, TaSiN, or RuTiN. The third conductive layer 30 includes a metal such as tungsten (W).

Each of the insulating capping patterns 33 includes a single layer or a plurality of layers 33a, 33b, and 33c that are sequentially stacked. The insulating capping patterns 33 are formed of a silicon nitride or a silicon nitride-based insulating material.

The semiconductor device 100 further includes spacer structures SP disposed on side surfaces of each of the bit lines BL.

Each of the spacer structures SP includes an inner spacer ISP, an outer spacer OSP, and an air gap AG between the inner spacer ISP and the outer spacer OSP.

Each of the bit lines BL includes a first bit line portion BLa on the buffer pattern 24 and a second bit line portion BLb that vertically overlaps the second impurity region 12b of the active region 9a. The first bit line portion BLa vertically overlaps the isolation region 9s.

The spacer structures SP include first spacer portions SP1 on first and second side surfaces IS_S1a and IS_S1b of the first bit line portion BLa and second spacer portions SP2 on third and fourth side surfaces IS_S2a and IS_S2b of the second bit line portion BLb. First and second side surfaces IS_S1a and IS_S1b of the first bit line portion BLa oppose each other, and third and fourth side surfaces IS_S2a and IS_S2b of the second bit line portion BLb oppose each other.

Each of the first spacer portions SP1 includes a first inner spacer ISP1, a first outer spacer OSP1, and a first air gap AG1 between the first inner spacer ISP1 and the first outer spacer OSP1. Each of the second spacer portions SP2 includes a second inner spacer ISP2, a lower insulating pattern LSP, a second outer spacer OSP2, and a second air gap AG2 between the second inner spacer ISP2 and the second outer spacer OSP2.

Hereinafter, the first side surface IS_S1a of the first bit line portion BLa and the first spacer portion SP1 that contacts the first side surfaces IS_S1a will be mainly described. In addition, the third side surfaces IS_S2a of the second bit line portion BLb and the second spacer portion SP2 that contacts the third side surface IS_S2a will be mainly described.

The first inner spacer ISP1 extends upward from a portion that contacts the side surface of the first bit line portion BLa to contact a side surface of the insulating capping pattern 33 on the first bit line portion BLa and to cover a side surface of the insulating capping pattern 33. The first inner spacer ISP1 extends downward along the first air gap AG1 from a portion that contacts the side surface of the first bit line portion BLa. A lower portion of the first inner spacer ISP1, disposed below the first air gap AG1, vertically overlaps the first air gap AG1.

The first inner spacer ISP1 includes a first portion ISP1a that is exposed by the first air gap AG1, and a second portion ISP1b that continuously extends from the first portion ISP1a, is disposed at a higher level than the first air gap AG1, and covers a surface (e.g., side surface) of the insulating capping pattern 33.

The first outer spacer OSP1 further includes a lower portion OSP_L that extends downward from a region exposed by the first air gap AG1 and inward from the buffer pattern 24. Accordingly, a lower end of the first outer spacer OSP1 is disposed at a level that is lower than that of a lower end of the first air gap AG1 and that of an upper surface of the buffer pattern 24.

The second inner spacer ISP2 extends upward from a portion that contacts the side surface of the second bit line portion BLb to contact the side surface of the insulating capping pattern 33 on the second bit line portion BLb and to cover the side surface of the insulating capping pattern 33. The second inner spacer ISP2 extends from a portion that contacts a side surface of the second bit line portion BLb to cover a lower surface and an external side surface of the lower insulating pattern LSP. The lower insulating pattern LSP is disposed below the second air gap AG2 and the second outer spacer OSP2. A lower surface of the second bit line portion BLb is disposed at a lower level than a lower surface of the first bit line portion BLa, and the lower insulating pattern LSP is disposed on a side surface of the lower region of the second bit line portion BLb.

The second inner spacer ISP2 includes a first portion ISP2a exposed by the first air gap AG1, a lower portion ISP2b disposed below the first portion ISP2a and that covers a lower surface of the first portion ISP2a and side surfaces and a lower surface of the lower insulating pattern LSP, and an upper portion ISP2c disposed above the first portion ISP2a and that covers a surface (e.g., side surface) of the insulating capping pattern 33.

The second outer spacer OSP2 further includes a lower portion OSP_L that extends downward from a region exposed by the second air gap AG2 to contact the lower insulating pattern LSP. Accordingly, a lower end of the second outer spacer OSP2 is disposed at a level that is lower than a level of a lower end of the second air gap AG2 and a level of an upper surface of the lower insulating pattern LSP. The lower insulating pattern LSP includes at least one of SiN or SiCN.

In each of the spacer structures SP, the inner spacer ISP includes the first and second inner spacers ISP1 and ISP2, the outer spacer OSP includes the first and second outer spacers OSP1 and OSP2, and the air gap AG includes the first and second air gaps AG1 and AG2.

The first spacer portion SP1 are substantially the same as one of the spacer structures described with reference to FIGS. 1, 3, 4, 5, and 6, such as SPa of FIG. 1, SPb of FIG. 3, SPc of FIG. 4, SPd of FIG. 5, or SPe of FIG. 6. For example, when the first spacer portion SP1 is substantially the same as the spacer structure described in FIG. 1 (SPa of FIG. 1), the first portion ISP1a of the first inner spacer ISP1 exposed by the first air gap AG1 is formed of substantially the same material as the inner spacer ISPa of FIG. 1, the first air gap AG1 has substantially the same width as the air gap AGa of FIG. 1, and the first outer spacer OSP1 exposed by the first air gap AG1 is formed of substantially the same material as the outer spacer OSPa of FIG. 1 and has substantially the same thickness as the outer spacer OSPa of FIG. 1. For example, the first portion ISP1a of the first inner spacer ISP1 exposed by the first air gap AG1 includes a first inner oxidized region ISP_O1 and a first inner non-oxidized region ISP_N1, and the first outer spacer OSP1 exposed by the first air gap AG1 includes a first outer oxidized region OSP_O1 and a first outer non-oxidized region OSP_N1. The first inner oxidized region ISP_O1, the first inner non-oxidized region ISP_N1, the first outer oxidized region OSP_O1, and the first outer non-oxidized region OSP_N1 correspond to the inner oxidized region ISP_O, the inner non-oxidized region ISP_N, the outer oxidized region OSP_O, and the outer non-oxidized region OSP_N described in FIG. 1, respectively. As described above, the first spacer portion SP1 is substantially the same as the spacer structure (SPa of FIG. 1) described with reference to FIGS. 1 and 2, but embodiments are not necessarily limited thereto, and the first spacer portion SP1 may be substantially the same as one of the spacer structures described with reference to FIGS. 3, 4, 5, and 6, such as SPb of FIG. 3, SPc of FIG. 4, SPd of FIG. 5, or SPe of FIG. 6.

One of the spacer structures SP includes the first spacer portion SP1 and the second spacer portion SP2. For example, the first inner spacer ISP1 of the first spacer portion SP1 and the second inner spacer ISP2 of the second spacer portion SP2 are integrated with each other, and have the same thickness and the same material. In addition, the first outer spacer OSP1 of the first spacer portion SP1 and the second outer spacer OSP2 of the second spacer portion SP2 are integrated with each other, and have the same thickness and the same material. In addition, the first air gap AG1 of the first spacer portion SP1 and the second air gap AG2 of the second spacer portion SP2 are continuously connected, and have the same width. Therefore, the first portion ISP2a of the second inner spacer ISP2 that is exposed by the second air gap AG2 in the second spacer portion SP2 includes a second inner oxidized region ISP_O2 and a second inner non-oxidized region ISP_N2, that respectively corresponds to the first inner oxidized region ISP_O1 and the first inner non-oxidized region ISP_N1 of the first inner spacer ISP1. Similarly, the second outer spacer OSP2 exposed by the second air gap AG2 includes a second outer oxidized region OSP_O2 and a second outer non-oxidized region OSP_N2 that respectively correspond to the first outer oxidized region OSP_O1 and the first outer non-oxidized region OSP_N1 of the first outer spacer OSP1.

Accordingly, in each of the spacer structures SP, the air gap AG and the inner and outer spacers ISP and OSP adjacent to the air gap AG or in contact with the air gap AG are the same as an air gap and inner and outer spacers of one of the spacer structures SPa, SPb, SPc, SPd, or SPe described above with reference to FIGS. 1 to 6.

The semiconductor device 100 further includes contact plugs CNT that are electrically connected to the first impurity regions 12a, and insulating fences 55 between the contact plugs CNT. Each of the contact plugs CNT includes first to third conductive layers 60, 63, and 66 that are sequentially stacked. The first conductive layer 60 is formed of doped polysilicon, such as N-type polysilicon. The first conductive layer 60 is electrically connected to the first impurity region 12a. The second conductive layer 63 includes a metal-semiconductor compound layer. For example, the metal-semiconductor compound layer includes at least one of WSi, TiSi, TaSi, NiSi, or CoSi. The third conductive layer 66 includes a plug pattern 66b and a conductive barrier layer 66a that covers a side surface and a bottom surface of the plug pattern 66b. The conductive barrier layer 66a includes at least one of TiN, TaN, WN, TiSiN, TaSiN, or RuTiN, and the plug pattern 66b includes a metal such as tungsten (W).

The second conductive layer 63 is disposed on a lower level than that of an upper end of the air gap AG. The third conductive layer 66 covers a portion of the spacer structure SP and a portion of an upper surface of the insulating capping pattern 33. Portions of the contact plugs CNT that are disposed at a higher level than the insulating capping pattern 33 may be referred to as landing pads 66P.

The insulating fences 55 are disposed between structures that include the bit lines BL and the insulating capping patterns 33, and are disposed between the contact plugs CNT.

The semiconductor device 100 further includes an upper insulating spacer 50 and an insulating separation structure 73. When viewed based on a single bit line BL and a single insulating capping pattern 33 that are sequentially stacked, the upper insulating spacer 50 covers an upper region and an upper end of the air gap AG and an upper region and an upper end of the outer spacer OSP on first sides of the upper region of the insulating capping pattern 33 corresponding to the side surfaces IS_S2a and IS_S1a of the bit line portions BLb and BLa, and is disposed between the contact plug CNT and an upper region of the insulating capping pattern 33.

The insulating separation structure 73 extends between the landing pads 66P and fills a downwardly extending recess portion 70.

When viewed based on the single bit line BL and the single insulating capping pattern 33 that are sequentially stacked, the insulating separation structure 73 covers an upper end of the air gap AG and an upper end of the outer spacers OSP on second sides of the upper region of the insulating capping pattern 33 corresponding to the side surfaces IS_S2b and IS_S1b of the bit line portions BLb and BLa. The insulating separation structure 73 includes an insulating material such as a silicon nitride.

The semiconductor device 100 further includes an etch-stop layer 80 and an information storage structure 90. The etch-stop layer 80 is disposed on the insulating separation structure 73 and is formed of an insulating material.

For example, the information storage structure 90 is a capacitor that stores information in a DRAM. For example, the information storage structure 90 may be a capacitor of a DRAM that includes first electrodes 82 that penetrate through the etch-stop layer 80 and electrically connect to the landing pads 66P, a dielectric layer 84 that covers the first electrodes 82 and the etch-stop layer 80, and a second electrode 86 disposed on the dielectric layer 84. The dielectric layer 84 includes at least one of a high-K dielectric, a silicon oxide, a silicon nitride, a silicon oxynitride, or combinations thereof.

For another example, the information storage structure 90 stores information of a memory that differs from a DRAM. For example, the information storage structure 90 is a capacitor of a ferroelectric memory (FeRAM) that includes a dielectric layer 84 disposed between the first and second electrodes 82 and 86 and includes a ferroelectric layer. For example, the dielectric layer 84 is a ferroelectric layer that writes data using a polarization state.

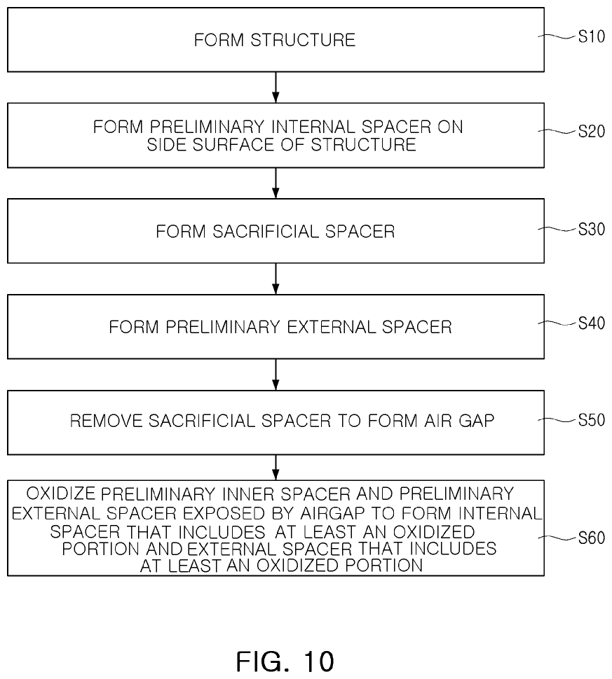

Hereinafter, an example of a method of fabricating a semiconductor device according to an embodiment will be described with reference to FIG. 10. FIG. 10 is a flowchart of a method of fabricating a semiconductor device according to an embodiment.

Referring to FIG. 10, in operation S10, a structure is formed. In an embodiment, the structure is the structure IS that includes conductive patterns CP and insulating capping patterns IP that are sequentially stacked as illustrated in FIG. 1. In an embodiment, the structure includes bit lines BL and the insulating capping patterns 33 that are sequentially stacked as illustrated in FIGS. 7 to 9.

In operation S20, a preliminary inner spacer is formed on a side surface of the structure. The preliminary inner spacer is formed of a SiCN material layer.

In operation S30, a sacrificial spacer is formed. The sacrificial spacer is formed of a material having an etch selectivity with respect to SiCN and SiN, such as a silicon oxide. The sacrificial spacer is formed on a side surface of the structure covered with the preliminary inner spacer.

In operation S40, a preliminary outer spacer is formed. In an embodiment, the preliminary outer spacer is formed of a SiN material. In an embodiment, the preliminary outer spacer is formed of a SiCN material and a SiN material that are sequentially stacked.

In operation S50, the sacrificial spacer is removed to form an air gap. The air gap is one of the above-described air gaps AGa, AGb, AGc, or AG.

In operation S60, the preliminary inner spacer and the preliminary outer spacer that are exposed by the air gap are oxidized to form an inner spacer that includes an oxidized portion and an outer spacer that includes an oxidized portion. A thermal oxidation process or a plasma oxidation process is used to oxidize the preliminary inner spacer and the preliminary outer spacer that are exposed by the air gap. Accordingly, a spacer structure that includes the air gap, the inner spacer that includes at least an oxidized portion, and the outer spacer that includes at least an oxidized portion, are formed. The spacer structure is one of the above-described spacer structures SP, SPa, SPb, SPc, SPd, or SPe.

As described above, according to exemplary embodiments, a semiconductor device that includes a spacer structure that includes an inner spacer, an outer spacer, and an air gap between the inner spacer and the outer spacer is provided. The spacer structure is disposed on a side surface of a conductive pattern, and the inner spacer contacts the side surface of the conductive pattern. The inner spacer includes an inner oxidized region, and the outer spacer includes an outer oxidized region and an outer non-oxidized region.

The inner oxidized region, the air gap, and the outer oxidized region of the spacer structure can reduce parasitic capacitance between adjacent conductive patterns and suppress a decrease in transmission speed of an electrical signal caused by an RC delay. Accordingly, electrical performance of the semiconductor device is increased.

According to exemplary embodiments, the inner spacer further includes an inner non-oxidized region that contacts the side surface of the conductive pattern. The inner non-oxidized region prevents a side surface of the conductive pattern from being oxidized and prevents resistance of the conductive pattern from increasing. The outer non-oxidized region of the outer spacer prevents electrical shorts from occurring between a contact plug adjacent to the conductive pattern and the conductive pattern. The conductive pattern may be a bit line of a memory device such as a DRAM.

As a result, a spacer structure according to exemplary embodiments increases the performance of a semiconductor device.

While exemplary embodiments have been shown and described above, it will be apparent to those skilled in the art that modifications and variations could be made without departing from the scope of embodiments of present inventive concept as defined by the appended claims.

What is claimed is:

1. A semiconductor device, comprising:
a conductive pattern; and
a spacer structure disposed on a side surface of the conductive pattern,
wherein the spacer structure includes:
an inner spacer in contact with the side surface of the conductive pattern;
an outer spacer that is spaced apart from the side surface of the conductive pattern; and
an air gap disposed between the inner spacer and the outer spacer,
wherein the inner spacer includes an inner oxidized region exposed by the air gap, and
a concentration of oxygen in the inner oxidized region has a gradient in which the oxygen concentration decreases in a direction away from the air gap.

2. The semiconductor device of claim 1, wherein
the inner oxidized region includes a silicon oxycarbonitride (SiOCN) material, and
a concentration of carbon in the inner oxidized region has a gradient in which the carbon concentration increases in the direction away from the air gap.

3. The semiconductor device of claim 1, wherein
the inner spacer further includes an inner non-oxidized region, and
the inner oxidized region is disposed between the inner non-oxidized region and the air gap.

4. The semiconductor device of claim 3, wherein
the inner non-oxidized region of the inner spacer is in contact with the side surface of the conductive pattern.

5. The semiconductor device of claim 3, wherein
the inner non-oxidized region of the inner spacer includes a silicon carbonitride (SiCN) material.

6. The semiconductor device of claim 1, wherein
the outer spacer includes:
an outer oxidized region exposed by the air gap; and
an outer non-oxidized region in contact with the outer oxidized region.

7. The semiconductor device of claim 6, wherein
a concentration of oxygen in the outer oxidized region has a gradient in which the oxygen concentration decreases in a direction away from the air gap.

8. The semiconductor device of claim 6, wherein
a material of the outer oxidized region differs from a material of the inner oxidized region.

9. The semiconductor device of claim 8, wherein
the outer oxidized region includes a silicon oxynitride (SiON) material, and
the inner oxidized region includes a silicon oxycarbonitride (SiOCN) material.

10. The semiconductor device of claim 6, wherein
the outer oxidized region includes a same material as the inner oxidized region.

11. The semiconductor device of claim 10, wherein
the inner oxidized region and the outer oxidized region each include a silicon oxycarbonitride (SiOCN) material, and
the outer non-oxidized region includes a silicon carbonitride (SiCN) material.

12. A semiconductor device, comprising:
a conductive pattern; and
a spacer structure disposed on a side surface of the conductive pattern,
wherein
the spacer structure includes:
an inner spacer in contact with the side surface of the conductive pattern;
an outer spacer that is spaced apart from the side surface of the conductive pattern; and
an air gap disposed between the inner spacer and the outer spacer,
wherein the inner spacer includes an inner oxidized region exposed by the air gap, and
the outer spacer includes an outer oxidized region exposed by the air gap, and an outer non-oxidized region in contact with the outer oxidized region.

13. The semiconductor device of claim 12, wherein
a thickness of the outer spacer is greater than a thickness of the inner spacer.

14. The semiconductor device of claim 13, wherein
the thickness of the outer spacer is greater than a width of the air gap.

15. The semiconductor device of claim 14, wherein
the width of the air gap is greater than the thickness of the inner spacer.

16. The semiconductor device of claim 14, wherein
the width of the air gap is less than the thickness of the inner spacer.

17. The semiconductor device of claim 13, wherein
the width of the air gap is greater than the thickness of the outer spacer.

18. A semiconductor device, comprising:
an active region;
an isolation region disposed on a side surface of the active region;
a gate structure disposed in a gate trench that intersects the active region and extends into the isolation region;
a first impurity region and a second impurity region disposed in the active region adjacent to the gate structure and that are spaced apart from each other;
a plurality of structures that intersect the gate structure at a higher level than a level of the gate structure;
a contact plug that includes a portion disposed between the plurality of structures and electrically connected to the first impurity region; and
spacer structures disposed on side surfaces of the plurality of structures,
wherein
each of the plurality of structures includes a bit line and an insulating capping pattern disposed on the bit line,
the bit line includes:
a first bit line portion disposed on the isolation region; and
a second bit line portion that includes a lower surface disposed at a level that is lower than a level of a lower surface of the first bit line portion, and that vertically overlaps the second impurity region,
each of the spacer structures includes a first spacer portion disposed on a side surface of the first bit line portion and a second spacer portion disposed on a side surface of the second bit line portion,
the first spacer portion includes:
a first inner spacer in contact with a side surface of the first bit line portion;
a first outer spacer; and
a first air gap disposed between the first inner spacer and the first outer spacer,
the second spacer portion includes:
a second inner spacer in contact with a side surface of the second bit line portion;
a second outer spacer; and
a second air gap disposed between the second inner spacer and the second outer spacer,
each of the first and second inner spacers includes an inner oxidized region,
a concentration of oxygen in the inner oxidized region of the first inner spacer has a gradient in which the oxygen concentration decreases in a direction away from the first air gap, and
a concentration of oxygen in the inner oxidized region of the second inner spacer has a gradient in which the oxygen concentration decreases in a direction away from the second air gap.

19. The semiconductor device of claim 18, wherein
a thickness of each of the first and second outer spacers is greater than a thickness of each of the first and second inner spacers,
each of the first and second outer spacers includes an outer oxidized region and an outer non-oxidized region,
the outer oxidized region of the first outer spacer has an oxygen concentration gradient in which a concentration of oxygen decreases in a direction away from the first air gap,
the outer oxidized region of the second outer spacer has an oxygen concentration gradient in which a concentration of oxygen decreases in a direction away from the second air gap,
each of the first and second inner spacers further includes an inner non-oxidized region in contact with the inner oxidized region,
the inner non-oxidized regions of the first and second inner spacers include a silicon carbonitride (SiCN) material,
the outer non-oxidized regions of the first and second outer spacers include a silicon nitride (SiN) material,
the inner oxidized regions of the first and second inner spacers include a silicon oxycarbonitride (SiOCN) material,
a concentration of carbon in the inner oxidized region of the first inner spacer has a gradient in which the carbon concentration increases in a direction away from the first air gap, and
a concentration of carbon in the inner oxidized region of the second inner spacer has a gradient in which the carbon concentration increases in a direction away from the second air gap.

20. The semiconductor device of claim 18, wherein
a thickness of each of the first and second inner spacers ranges from 7 angstroms to 25 angstroms.
